(19) United States
(12) Patent Application Publication
(10) Pub. No.: US 2007/0025420 A1
(43) Pub. Date: Feb. 1, 2007

(54) Transmission and detection in ultrawide band communications

(75) Inventor: Xiaodai Dong, Victoria (CA)

Correspondence Address: KLARQUIST SPARKMAN, LLP, 121 SW SALMON STREET, SUITE 1600, PORTLAND, OR, 97204, US

(73) Assignee: University of Victoria Innovation and Development Corporation

(21) Appl. No.: 11/400,470

(22) Filed: Apr. 6, 2006

Related U.S. Application Data
(60) Provisional application No. 60/681,918, filed on May 16, 2005.

(51) Int. Cl. H04B 1/00; H03K 9/04

(52) U.S. Cl. 375/130; 375/239

(57) ABSTRACT

A method of transmitting information on ultra-bandwidth systems is provided. The method can double the data rate of existing methods. The method comprises sending and receiving an ultra-wideband pulse. The ultra-wideband pulse comprises at least a dual pulse (two sub-pulses) of time T_{w} and is sent during a frame interval of time T_{f}. The sub-pulses are sent repeatedly, and T_{f} is larger than T_{w}. The method can permit multipath energy collection, simple timing acquisition, simple implementation and robustness.

### RELATED APPLICATIONS

This application claims priority from U.S. provisional patent application Ser. No. 60/681,918 entitled TRANSMISSION AND DETECTION IN ULTRAWIDE BAND COMMUNICATIONS, filed 16 May 2005, which is incorporated herein by reference.

### FIELD

This application relates to a method and system of transmitting information using ultra-wideband impulse radio. More specifically, the application relates to a transmission technique employing dual sub-pulses.

### BACKGROUND

Ultra-wideband (UWB) systems employ very narrow, low power pulses to carry information. It has attracted significant interest recently as the Federal Communications Commission (FCC) has approved its unlicensed usage. That means a UWB system can be deployed to co-exist with current licensed systems in the same frequency bands with no license cost. The vast bandwidth it occupies bears the potential to transmit information at very high data rate. UWB impulse radio has found applications in communications, ground penetrating radar, imaging, and collision detection and avoidance, for example.

Typically, a UWB impulse radio communication system employs very narrow pulses for transmission and the extremely short duration of these pulses leads to high multipath resolution. The receiver is a coherent receiver. In other words, a UWB channel will transform a single transmitted pulse into a long train of resolvable random pulses, and each received pulse exhibits less severe fading than in narrowband or wideband systems. Although the resolvable multipaths provide diversity that can be employed to enhance performance, the challenge for the receiver is how to efficiently capture the energy from all these multipaths. If a rake structure is used, a large number of rake fingers must be implemented, which is prohibited in practice because of the associated high complexity and high cost. Moreover, a UWB channel may distort the shape of the transmitted pulse [1]. Due to the ultra wide bandwidth, distinct frequency components in a signal may react differently to propagation environments. A receiver filter matched to the transmitted pulse in coherent detection such as a rake receiver may not work well if the pulse shape is distorted by the channel.

The UWB transmitted reference (TR) system was developed to overcome the deficiencies in the coherent receiver system. It was first proposed in [2] and [3], where a reference pulse and a modulated pulse separated by delay D seconds constitute a pulse pair to represent one bit of information. The delay D is larger than the maximum delay spread of the channel plus one pulse duration to avoid the interference between the received reference pulse and the data pulse [2]. It was demonstrated that UWB-TR systems have simple implementation and robust performance. Performance analysis of UWB transmitted reference was first presented in [4], while optimal and suboptimal receivers were derived and analyzed in [5]. The authors in [6] presented a generalized optimal receiver structure that takes into account variable number of reference and data pulses. A different generalization of the TR technique was proposed in [7], where a signaling set is composed of sequences of pulses with different delays and weights. In [9], the authors studied a pilot waveform assisted modulation scheme that can be considered as another type of generalization of the TR method. In [8], the performance of multiple pulse multiple delay modulation for UWB multiple access was investigated. Also, a differential UWB scheme was proposed in [10].

The TR method in general has several advantages over a coherent receiver. It does not require explicit channel estimation, or a large number of fingers in a rake receiver. It is robust to possible channel distortion on pulse shape. Easy and simple synchronization makes it a good candidate for bursty traffic. However, there are also drawbacks of the TR system. These include the fact that the performance is inferior to ideal coherent detection and lower data rates because of the transmission of reference signals. The need for a spaced frame length delay between the reference pulse and the data pulse in a TR system further slows the data rate. Further, a long delay such as needed in TR is difficult to implement. Also related to the spaced frame length delay, is the fact that there is a time constraint on the number of reference sub-pulses that can be received because of the time delay. As the reference sub-pulses assist in reducing noise, there is a limit to the amount of noise reduction possible.

The UWB channel model proposed by the Institute of Electrical and Electronic Engineers (IEEE) 802.15.3a Working Group [11] is modeled as a log-normal faded multipath channel with log-normal shadowing and exponential power delay profiles. The paths arrive in clusters, and both the cluster arrival rate and the ray arrival rate follow Poisson distributions. In its simplest form, the channel can be generally represented as

$$h ( t ) = {\sum }_{k = 1}^{K} {α}_{k} δ ( t - {τ}_{k} )$$

where K multipaths have amplitude αₖ's and delay τₖ's. The frame interval T_{f} is assumed to be larger than the length of the channel impulse response plus the dual pulse duration T_{w} so that there is no interference from the previous or succeeding transmitted pulses. This channel model simulates well the realistic UWB channels and therefore is adopted here to study the disclosed scheme.

It is an object of the present application to overcome the deficiencies of the prior art.
[1] M. Z. Win and R. A. Scholtz, “Characterization of ultra-wide bandwidth wireless indoor channels: a communication-theoretic view,” IEEE J select. Areas Commun., vol. 20, pp. 1613-1627, December 2002.
[2] R. Hoctor and H. Tomlinson, “Delay-hopped transmitted-reference RF communications,” IEEE Conf. Ultra Wideband Systems and Techno., pp. 265-269, May 2002.
[3] N. Van Stralen, A. Dentinger, K. Welles, II., R. Gaus, R. Hoctor and H. Tomlinson, “Delay hopped transmitted-reference experimental results,” IEEE Conf. Ultra Wideband Systems and Techno., pp. 93-98, May 2002.
[4] J. D. Choi and W. E. Stark, “Performance of ultra-wideband communications with suboptimal receivers in multipath channels,” IEEE J Selected Areas Commun., vol. 20, pp. 1754-1766, December 2002.
[5] Y.-L. Chao and R. A. Scholtz, “Optimal and suboptimal receivers for ultra-wideband transmitted reference systems,” Globecom' 2003, San Francisco, USA, pp. 759-763, December 2003.
[6] S. Franz and U. Mitra, “On optimal data detection for UWB transmitted reference systems,” Globecom' 2003, pp. 744-748, December 2003.
[7] H. Zhang and D. L. Goeckel, “Generalized transmitted-reference UWB systems,” IEEE Conf. Ultra Wideband Systems and Techno., pp. 16-19, 2003.
[8] L. Yang and G. Giannakis, “Optimal pilot waveform assisted modulation for ultra-wideband communications,” to appear in the IEEE Trans. Wireless Commun.
[9] F. Nekoogar and F. Dowla, “On the performance of multiple pulse multiple delay UWB modulation,” Wireless 2003, Calgary, Alberta, Canada, pp. 219-225, July 2003.
[10] M. Ho, V. Somayazulu, J. Foerster and S. Roy, “A differential detector for an ultra-wideband communications systems,” IEEE Vehicular Technology Conf., pp. 1896-1900, May 2002.
[11] J. Foerster, Channel modeling subcommittee report (Final), IEEE802.15-03/490r1, Feb.\ 2003 (http://grouper.ieee.org/groups/802/15/pub/2003/Mar03/).

### SUMMARY

A method of transmitting information on ultra-wideband systems is provided. The method may double the data rate of existing methods. In one embodiment, the method comprises sending and receiving an ultra-wideband pulse. The ultra-wideband pulse is of time T_{w} and is sent during a frame interval T_{f}. The ultra-wideband pulse comprises at least two sub-pulses, sub-pulse one and sub-pulse two, wherein said sub-pulses are contiguous, and T_{f} is larger than T_{w}. The method permits multipath energy collection, simple timing acquisition, simple implementation and robustness.

In another embodiment, the method comprises repeatedly sending and receiving said ultra-wideband pulse contiguously within a frame.

In another embodiment, sub-pulse two is identical to sub-pulse one.

In another embodiment, the method is for use in on-off keying.

In another embodiment, the method is for use in pulse position modulation.

In another embodiment, sub-pulse two is inverse to or identical to sub-pulse one.

In another embodiment, the method is for use in binary pulse amplitude modulation.

In another embodiment, the method is for use in pulse amplitude modulation.

In another embodiment, the method comprises multiple access techniques.

In another embodiment, the multiple access technique comprises time-hopping.

In another embodiment, the multiple access technique comprises spreading sequence.

In another embodiment, an auto-correlation receiver is operative for receiving said ultra-wideband pulse.

In another embodiment, a transmission system for transmitting ultra-wideband pulses is provided. The system is operative to send at least one ultra-wideband pulse during a frame interval of time T_{f}, and comprises a transmitter operative to send an ultra-wideband pulse of time T_{w} and a receiver. The ultra-wideband pulse comprises at least two sub-pulses, sub-pulse one and sub-pulse two and the sub-pulses are contiguous. T_{f} is larger than T_{w} as there is additional blank time in T_{f}. The receiver is operative to receive the ultra-wideband pulse.

In another embodiment, the system further comprises a transmitter operative to repeatedly send said ultra-wideband pulse contiguously within a frame.

In another embodiment, the transmitter is operative to send identical sub-pulse one and sub-pulse two.

In another embodiment, the system is for use in on-off keying.

In another embodiment, the system is for use in pulse position modulation.

In another embodiment, the transmitter is operative to send sub-pulse two inverse to or identical to sub-pulse one.

In another embodiment, the system is for use in binary pulse amplitude modulation.

In another embodiment, the system is for use in pulse amplitude modulation.

In another embodiment, the system further comprises multiple access techniques.

In another embodiment, the multiple access technique comprises time-hopping. In another embodiment, the multiple access technique comprises spreading sequence.

In another embodiment, the system further comprises an auto-correlation receiver operative to receive said ultra-wideband pulse.

### BRIEF DESCRIPTION OF THE DRAWINGS

FIG. 1 is an illustration of the transmitted dual pulse structure for OOK and binary PAM in accordance with a described embodiment.

FIG. 2 is a DP transmitter using binary PAM modulation.

FIG. 3 is a DP-Int Receiver for binary PAM and OOK.

FIG. 4 is a DP “GSC” type receiver for binary PAM and OOK. The input signal r(t) is obtained by passing the received signal through a lowpass filter as in FIG. 3.

FIG. 5 is a comparison between DP and TR in CM1.

FIG. 6 is a comparison between DP and TR in CM2.

FIG. 7 is a comparison between DP and TR in CM3.

FIG. 8 is a comparison between DP and TR in CM4.

FIG. 9 Multiple pulses in a frame, in accordance with an embodiment of the invention: (a) No space between the reference sub-pulse and the data sub-pulse; (b) A small space between the reference sub-pulse and the data sub-pulse

FIG. 10 A UWB symbol structure in which S represents a frame structure as illustrated in FIG. 9.

FIG. 11 An auto-correlation receiver for multiple dual pulse binary PAM and OOK, in accordance with an embodiment of the invention.

FIG. 12 BER of auto-correlation and non-coherent detection of the DP signal given by FIG. 9(a) in IEEE 802.15.4a channels CM1 and CM8.

### DETAILED DESCRIPTION

Definitions:

The following outlines the pulse types for the various systems contemplated for use:

PPM (binary and non-binary): identical sub-pulses

OOK (binary in nature): identical sub-pulses

Binary PAM: sub-pulse two can be either identical or inverse to sub-pulse one, depending on the information data it represents.

Non-binary PAM(called M-ary PAM): sub-pulse two is either identical to or inverse to a scaled sub-pulse one, depending on the information data it represents (information data b= . . . ,−5, −3, −1, +1, +3, +5, . . . ).

Quaternary phase shift keying (QPSK), also called 4-ary biorthogonal keying (4BOK): two binary PAM on in-phase and quadrature components.

Overview:

Four detection schemes with different implementation complexity and their performances, as determined by Monte-Carlo simulations are disclosed.

In view of the many possible embodiments to which the principles of the claimed invention may be applied, it should be recognized that the illustrated embodiments are only preferred examples and should not be taken as limiting the scope of the invention. Rather, the scope of the invention is defined by the following claims. I therefore claim as my invention all that comes within the scope and spirit of these claims.

Description:

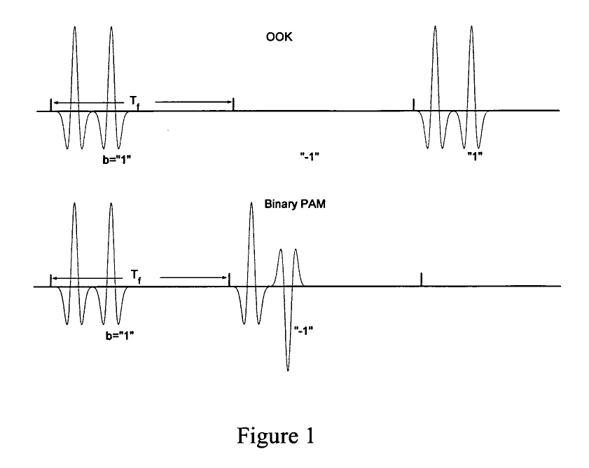

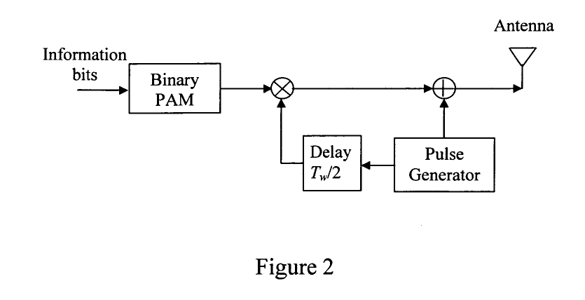

A reference sub-pulse is used together with a modulated sub-pulse to constitute a dual pulse (DP) structure as the basic transmission unit such that the first half of the pulse is either identical or inverse to the second half. FIG. 1 illustrates the dual pulse structure and FIG. 2 shows the transmitter block diagram. FIG. 2 shows a block diagram for one embodiment of a transmitter. The transmitter comprises a modulation block into which information bits are fed. In this case, the modulation scheme is pulse amplitude modulation (PAM). Pulses from a pulse generator pass through a delay block which provides a delay of T_{w}/2. The delayed pulses are mixed with the modulated information bits. This signal is then summed with additional pulses from the pulse generator and transmitted via an antenna.

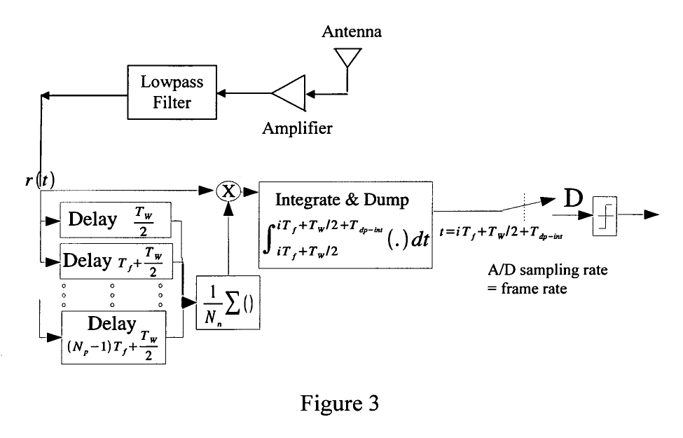

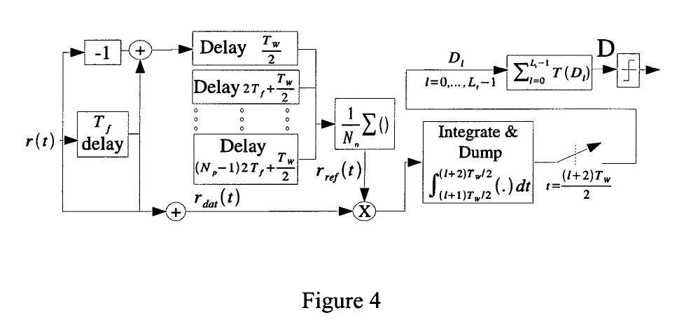

Since the two narrow sub-pulses are of the same shape and one after another, the channel affects them in a similar manner. FIGS. 3-4 depict an autocorrelation receiver block diagram. For each resolvable multipath, the first half portion of the received pulse is used as a noisy reference for detection and energy collection of the second half, i.e., the modulated sub-pulse. The autocorrelation receiver performs essentially non-coherent detection.

FIG. 3 depicts one embodiment of a DP-Int Receiver for binary PAM and on-off keying (OOK). The received signal passes through an amplifier and a lowpass filter. This signal is mixed with a noise-averaged version of itself and then processed in an integrate-and-dump block. The resulting signal is then sampled at a frame rate.

FIG. 4 depicts one embodiment of a DP “GSC” type receiver for binary PAM and OOK modulation schemes. A received signal passes through an antenna and a lowpass filter (not shown). The signal is summed with delayed and inverted versions of itself, and then mixed with a noise-averaged version of the signal. After the signal is processed in an integrate-and-dump block, it is sampled and processed according to the test function T(Dₗ) explained above.

Transmission Technique

In this system, a basic ultra-wideband pulse p(t) of duration T_{w} is composed of two sub-pulses: the sub-pulse gₜᵣ(t) which has non-zero value in the first half interval [0, T_{w}/2] and the sub-pulse s₂(t) in the second half interval [T_{w}/2, T_{w}]. The energy of gₜᵣ(t) is E_{b}/2. The sub-pulse s₂(t) has a certain relationship with the first sub-pulse gₜᵣ(t) depending on the particular modulation format used. In other words, the sub-pulses are identical and there is no modulation. Pulse amplitude modulation (PAM), on-off keying (OOK) and pulse position modulation (PPM) are commonly used modulation schemes in UWB communications systems. Here we use binary modulation formats as examples, including binary PAM and binary PPM. For on-off keying and pulse position modulation,

$${s}_{2} ( t ) = \{ \begin{matrix}{g}_{tr} ( t - {T}_{w} / 2 ) , & {T}_{w} / 2 \leq t \leq {T}_{w} \\ 0 , & elsewhere\end{matrix}$$

and hence the UWB pulse p(t) is given by
p(t)=gₜᵣ(t)+gₜᵣ(t−T_{w}/2), 0≦t≦T_{w}.

In these cases, the basic unit of a UWB pulse is composed of two identical sub-pulses. For binary PAM, however,

$${s}_{2} ( t ) = \{ \begin{matrix}b \cdot {g}_{tr} ( t - {T}_{w} / 2 ) , & {T}_{w} / 2 \leq t \leq {T}_{w} \\ 0 , & elsewhere\end{matrix} \\ and \\ p ( t ) = {g}_{tr} ( t ) + b \cdot {g}_{tr} ( t - {T}_{w} / 2 ) , 0 \leq t \leq {T}_{w}$$

where b=+1/−1 is the binary PAM modulated information bit, or the communications source. For M-ary PAM, b is an M-ary alphabet. The energy of the UWB pulse p(t) is E_{b}. FIG. 1 illustrates the dual pulse structure for OOK and binary PAM. For binary PAM, the sub-pulses can be identical or one can be the inverse of the other. Other modulation schemes can also be applied to the basic pulse unit that consists of two identical sub-pulses. The choice of modulation format is application dependent.

The modulated UWB pulses are transmitted with intervals of T_{f}, denoted as the frame length. The same dual pulse can be sent Nₛ times to increase the transmission reliability (see below for further description). Multiple access techniques such as time-hopping or spreading sequence can be used along with this pulse scheme. A binary PAM modulated signal for transmission can then be expressed as

$${s}_{tr}^{PAM} ( t ) = {{\sum }^{∞}}_{i = - ∞} {g}_{tr} ( t - {iT}_{f} ) + {b}_{⌊ i / {N}_{s} ⌋} \cdot {g}_{tr} ( t - {iT}_{f} - {T}_{w} / 2 )$$

where └∩┘denotes the floor function and b_{└i/N}_{ₛ}_{┘} is either 1 or −1.

An OOK modulated signal is given by

$${s}_{tr}^{OOK} ( t ) = {\sum }_{i = - ∞}^{∞} {b}_{⌊ i / {N}_{s} ⌋} [ {g}_{tr} ( t - {iT}_{f} ) + {g}_{tr} ( t - {iT}_{f} - {T}_{w} / 2 ) ]$$

where b_{└i/N}_{ₛ}_{┘} is either 0 or 1. A binary PPM signal is given by

$${s}_{tr}^{PPM} ( t ) = {\sum }_{i = - ∞}^{∞} {g}_{tr} ( t - {iT}_{f} - {b}_{⌊ i / {N}_{s} ⌋} δ ) + \cdot {g}_{tr} ( t - {iT}_{f} - {T}_{w} / 2 - {b}_{⌊ i / {N}_{s} ⌋} δ )$$

where b_{└i/N}_{ₛ}_{┘} is either 0 or 1, and δ is the time displacement of PPM.

The pulse scheme can also be viewed as having the first half shape either the same as or inverse to the second half shape. The design of the pulse shapes gₜᵣ(t) and p(t) should take into account, for example, but not limited to, the FCC spectrum mask, the potential narrowband interference, and implementation issues, as would be known to one skilled in the art. The DP transmission scheme is not limited to any particular pulse shape.

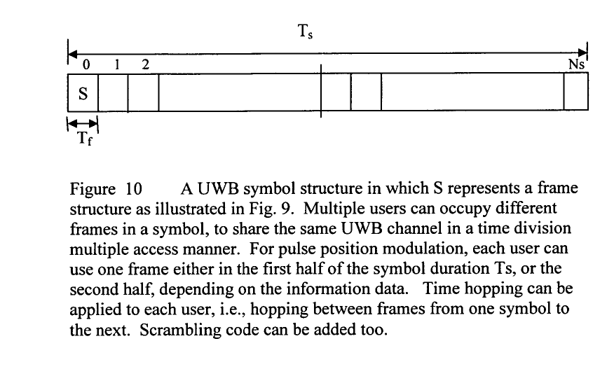

As noted above, multiple dual pulses can be transmitted in a frame. These pulses are sent contiguously within a frame. One symbol is composed of Nₛ frames, shown in FIG. 10. Consider the general scenario where there is more than one user in the network, then each user can occupy a unique frame in one symbol duration Tₛ. This is the so called time division multiple access scheme for several users to share a common UWB channel.

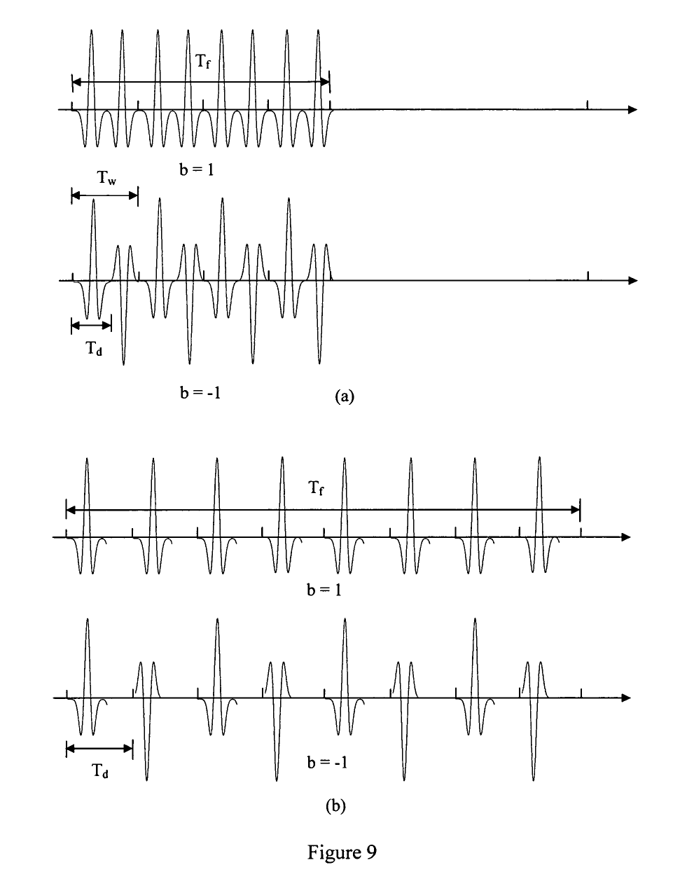

For each user, a frame is composed of consecutive multiple dual pulses, as illustrated in FIG. 9(a). We refer to the multiple-dual-pulse structure as a composite dual pulse S. FIG. 9(a) shows a binary pulse amplitude modulated (PAM) transmitted signal frame. If pulse position modulation (PPM) is the choice of the modulation scheme, either the “b=1” or “b=−1” composite dual pulse can be used. Then the composite dual pulse is placed at one frame in the first half of a symbol interval or the second half of a symbol interval, corresponding to binary information data being “0” or “1”.

Time hopping can be performed on a composite dual pulse from symbol to symbol. That means, a composite dual pulse of one user can hop from one frame position to another in different symbols. For example, for symbol 0, user 1's composite dual pulse occupies the 0-th frame, and for symbol 1, user 1 occupies the 5-th frame, etc. Similarly, a scrambling code sequence of length N, c=[c₀, c₁, . . . , c_{N-1}], can be applied onto the composite dual pulses of N symbols. The multiple dual pulses in a composite dual pulse are always weighted by the same code symbol cᵢ.

FIG. 9(b) shows a slight variation of FIG. 9(a), where there is a gap T_{d} between the reference sub-pulse and the data sub-pulse. For such an arrangement to work, all sub-pulses, reference and data, should be evenly spaced in a frame. The sub-pulses may be separated by about 10 nanoseconds, for example (approximately three sub-pulse lengths, for example). The gap T_{d} is, however, much smaller than the UWB channel length. Usually it is less than 10 ns for practical implementation. In FIG. 9(a), T_{d} is exactly half the dual pulse width, T_{w}/2.

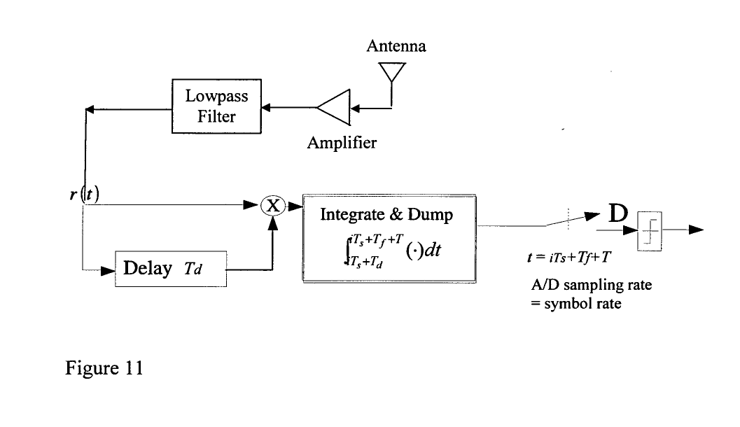

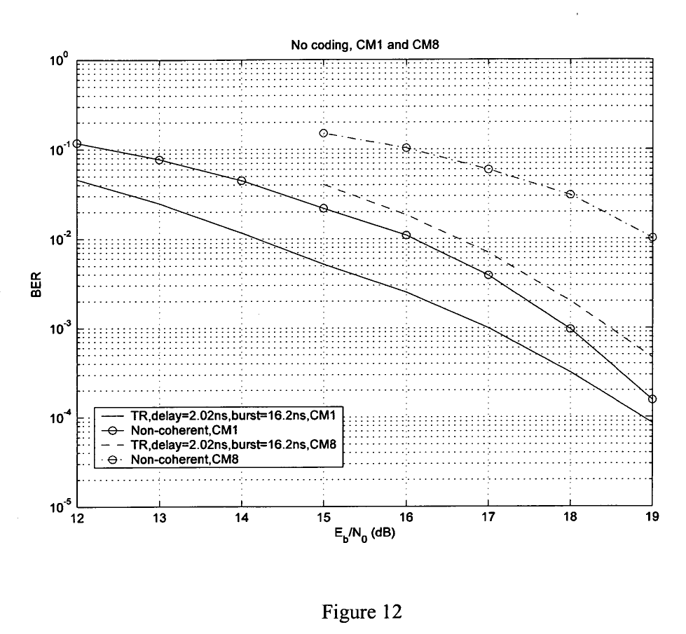

The receiver for multiple dual pulses is shown in FIG. 11. There is only one delay unit with small delay T_{d}, which makes it suitable for practical implementation. The integration length must go beyond the frame length T_{f}, and T (<<Tₛ) is sufficiently long to capture the majority of the channel energy. A performance plot of the DP signal with 8 consecutive DP pulses in FIG. 9(a) is given in FIG. 12. Two receivers are employed, the DP receiver given in FIG. 11 and a simple non-coherent energy detection as proposed in Ismail Lakkis, Modulation summary for TG4a, document # IEEE 15-05-617-01-004a, October 2005, the IEEE 802.15.4a working group. The DP auto-correlation receiver achieves better performance than the non-coherent receiver.

Detection Technique

The received signal over one symbol duration (one-shot) is given by

$$r ( t ) = {\sum }_{i = 0}^{{N}_{s} - 1} {\sum }_{k = 1}^{K} {α}_{k} {g}_{rx} ( t - {iT}_{f} - {τ}_{k} ) + {α}_{k} b \cdot {g}_{rx} ( t - {iT}_{f} - {T}_{w} / 2 - {τ}_{k} ) + \tilde{n} ( t ) for binary PAM$$

$$r ( t ) = {\sum }_{i = 0}^{{N}_{s} - 1} {\sum }_{k = 1}^{K} {α}_{k} b [ {g}_{sx} ( t - {iT}_{f} - {τ}_{k} ) + {g}_{rx} ( t - {iT}_{f} - {τ}_{k} ) + {g}_{tr} ( t - {iT}_{f} - {T}_{w} / 2 - {τ}_{k} ) ] + \tilde{n} ( t ) for OOK$$

where ñ(t) is the zero mean additive white Gaussian noise with variance N₀/2 and gᵣₓ(t) is the received pulse shape corresponding to the transmitted gₜᵣ(t). This representation is valid for the general case where there is mismatch between gᵣₓ(t) and gₜᵣ(t). The receiver first passes the received signal through a lowpass filter that has one-sided bandwidth Wand unit magnitude. The bandwidth of the lowpass filter is large enough that the information bearing signal is passed without distortion and the noise is limited to within the filter bandwidth. The noise process after the lowpass filter is denoted by n(t).

In a preferred embodiment, the receiver does not have any channel state information. In other words, neither channel path strengths nor channel path delays are known or estimated at the receiver. The autocorrelation receiver first multiplies the received signal by its T_{w}/2-delayed version and then integrates the product. Depending on the integration interval, there are at least four possible designs to obtain the decision variable:
1) Direct Integration

$$D = {\sum }_{i = 0}^{{N}_{s} - 1} {\int }_{{jT}_{f} + {T}_{w} / 2}^{{jT}_{f} + {T}_{w}} r ( t ) {\sum }_{m = - {N}_{p} / 2}^{{N}_{p} / 2} \frac{1}{{N}_{p}} r ( t + {mT}_{f} - {T}_{w} / 2 ) ⅆ t for PAM and OOK$$

$${D}_{k} = {\sum }_{i = 0}^{{N}_{s} - 1} {\int }_{{jT}_{f} + {T}_{w} / 2 + k δ}^{{jT}_{f} + {T}_{tr} + k δ} r ( t ) {\sum }_{m = - {N}_{p} / 2}^{{N}_{p} / 2} \frac{1}{{N}_{p}} r ( t + {mT}_{f} - {T}_{w} / 2 ) ⅆ t , k = 0 , 1 for PPM$$

where Tₜᵣ(<T_{f}) is the integration length and Nₚ is the number of frames used for the received reference sub-pulse noise averaging. If Nₚ=1 then there is no noise averaging applied. This is the simplest method and simulation shows that it yields comparable performance to the below 3 schemes. This receiver scheme is referred to as “DP-Int”. A simple block diagram of the DP-Int receiver structure is given in FIG. 3.

In the other 3 methods, the receiver first multiplies the received signal by its T_{w}/2-delayed version and then integrates the product every T_{w}/2 seconds. For PAM and OOK,

$${D}_{l} = {\sum }_{i = 0}^{{N}_{s} - 1} {\int }_{{jT}_{f} + {lT}_{w} / 2}^{{jT}_{f} + {lT}_{w} / 2 + {T}_{w} / 2} r ( t ) {\sum }_{m = - {N}_{p} / 2}^{{N}_{p} / 2} \frac{1}{{N}_{p}} r ( t + {mT}_{f} - {T}_{w} / 2 ) ⅆ t , l = 0 , 1 , … {L}_{t} - 1$$

where Lₜ=2T_{mds}/T_{w} is the total number of possible paths and T_{mds} is the maximum delay spread of the channel. For PPM,

$${D}_{l , k} = {\sum }_{i = 0}^{{N}_{s} - 1} {\int }_{{jT}_{f} + {lT}_{w} / 2 + k δ}^{{jT}_{f} + {lT}_{w} / 2 + {T}_{w} / 2 + k δ} r ( t ) {\sum }_{m = - {N}_{p} / 2}^{{N}_{p} / 2} \frac{1}{{N}_{p}} r ( t + {mT}_{f} - {T}_{w} / 2 ) ⅆ t , l = 0 , 1 , … {L}_{t} - 1 , k = 0 , 1.$$

A simple block diagram of the receiver structure is given in FIG. 4 where T(Dₗ) is a test function that corresponds to three possible ways a receiver has to form a decision variable D from Lₜ independent Dₗ's.

2) Generalized Selection Combining (GSC)

In this method, we select and sum the L number of {Dₗ|l=0, 1, . . . , Lₜ−1} with the largest absolute values |Dₗ|'s. Define a test function

$$T ( {D}_{l} ) = \{ \begin{matrix}{D}_{l} , & if \vert {D}_{l} \vert \geq \vert {D}^{( L )} \vert \\ 0 , & if \vert {D}_{l} \vert < \vert {D}^{( L )} \vert\end{matrix}$$

where D^{(L)} is the one that has the L-th largest absolute value among all Dₗ's. The decision variable of this generalized selection combining is hence given by

$$D = {\sum }_{l = 0}^{{L}_{t} - 1} T ( {D}_{l} ) for PAM and OOK$$

$${D}_{k} = {\sum }_{l = 0}^{{L}_{t} - 1} T ( {D}_{l , k} ) , k = 0 , 1 for PPM$$

3) Absolute Threshold Generalized Selection Combining (AT-GSC)

This method compares each autocorrelation output Dₗ to a fixed threshold Dₜₕ (>0). All the Dₗ's with absolute values larger than Dₜₕ are then selected and combined. Defining the absolute threshold test function

$${y}_{l} = T ( {D}_{l} ) = \{ \begin{matrix}{D}_{l} , & if \vert {D}_{l} \vert \geq {D}_{th} \\ 0 & if \vert {D}_{l} \vert < {D}_{th}\end{matrix} ,$$

the decision variable D is given by

$$D = {\sum }_{l = 0}^{{L}_{t} - 1} {y}_{l}$$

for PAM and OOK, and

$${D}_{k} = {\sum }_{l = 0}^{{L}_{t} - 1} T ( {D}_{l , k} )$$

for PPM.
4) Normalized Threshold Generalized Selection Combining

Normalized threshold GSC differs from AT-GSC in how the threshold is determined. Instead of using a preset absolute threshold value, NT-GSC forms its threshold as a fixed fraction ηₜₕ of Dₘₐₓ|Dₗ|, i.e., Dₜₕ=ηₜₕ Dₘₐₓ. Define

$${z}_{l} = T ( {D}_{l} ) = \{ \begin{matrix}{D}_{l} , & if \vert {D}_{l} \vert \geq {η}_{th} {D}_{max} \\ 0 & if \vert {D}_{l} \vert < {η}_{th} {D}_{max}\end{matrix}$$

where T(x) is the normalized threshold test function. The decision variable is

$$D = {\sum }_{l = 0}^{{L}_{t} - 1} {z}_{l}$$

for PAM and OOK, and

$${D}_{k} = {\sum }_{l = 0}^{{L}_{t} - 1} T ( {D}_{l , k} )$$

for PPM.

Unlike the combining in rake receivers, the different noncoherent combining schemes here are easy to implement, since the single integrate-and-dump device has already output all Dₗ's and it is only a matter of computing (likely in a DSP) the decision statistics D.

The final decision is made depending on the modulation format used. For binary PAM, the information data is detected as 1 (or 0 in binary format) if D>0, and −1 (or 1 in binary format) if D<0. For OOK, the information data is detected as 1 if D>TH, and 0 if D<TH where TH is a positive threshold. For PPM, the information data is detected as 0 if D₀>D₁, and 1 if D₀<D₁

Error Performance

The sub-pulse used in the simulation embodiment is the second derivative of the Gaussian pulse gₜᵣ(t)={1−4π[(t−T′_{w}/2)/T_{d}]²}exp{−2π[(t−T′_{w}/2)/T_{d}]²}, where T_{d}=0.2877 ns and the sub-pulse width T′_{w} is set at 0.7 ns. The receiver lowpass filter with Hamming window has 50 taps and a bandwidth of 14.4 GHz. The simulation sampling rate is 30 GHz. For each channel model, the bit error probability is obtained from averaging the bit error rate (BER) over 100 channel realizations.

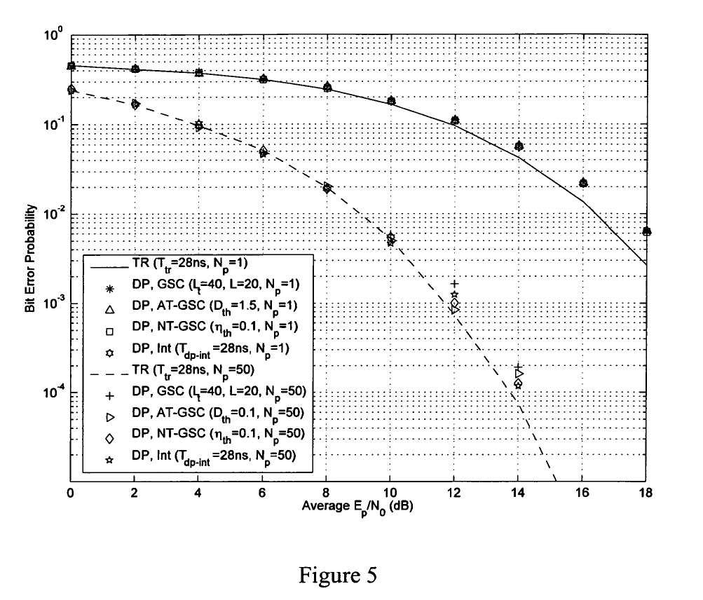

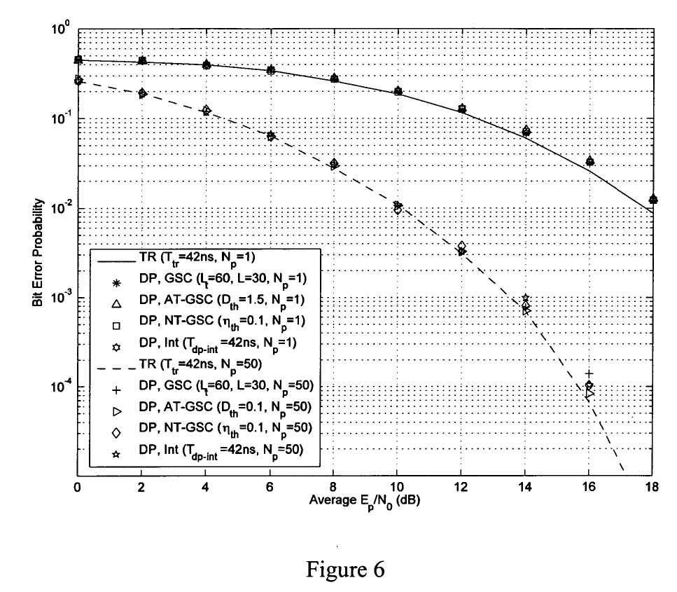

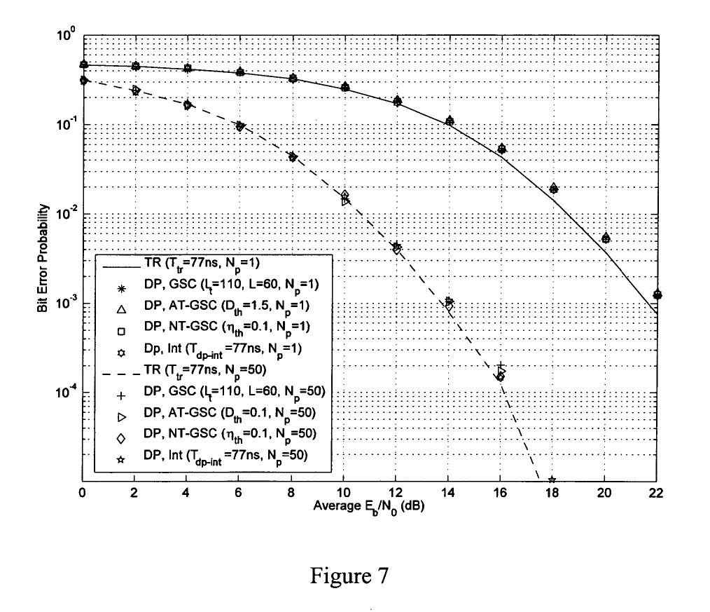

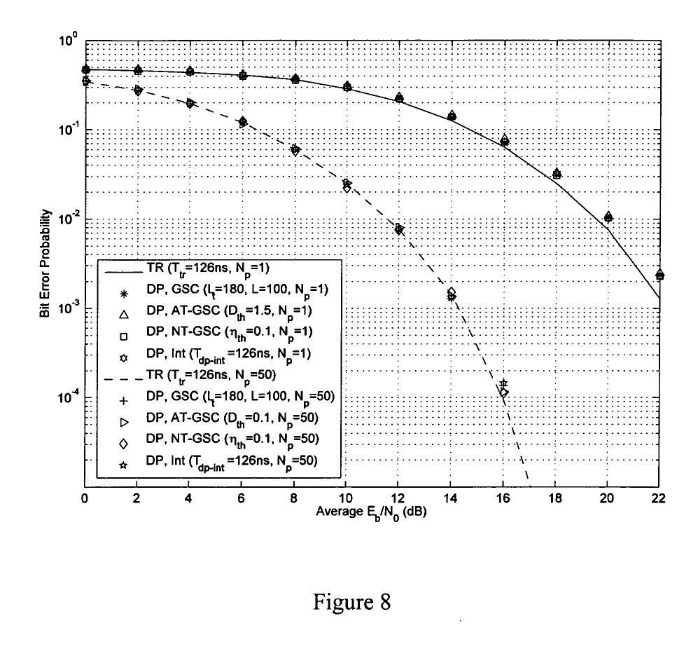

FIGS. 5-8 plot the simulated BER performance of the DP system and the conventional TR technique in UWB channels CM1-CM4, respectively. All three diversity combining schemes in DP schemes are simulated. Averaging the received reference sub-pulse signal over Nₚ=50 frames to reduce the noise in the reference template is also performed in these figures. As expected, the performance is significantly improved with noise averaging in all plots. For the TR system, the integration of the product between the received signal and its frame delayed version is over an interval less than the whole frame duration so that the noisy trail close to the end of the frame is not included in the decision variable. This results in better performance than integrating over the whole frame duration. The integration length is denoted as Tₜᵣ in these figures.

For the DP scheme with Nₛ=1 in the four channel models studied, the GSC, AT-GSC and NT-GSC receivers have similar performance using the parameters shown in FIGS. 5-8, with or without reference sub-pulse noise averaging. The number of branches selected in GSC, the absolute threshold in AT-GSC and the normalized threshold in NT-GSC are parameters whose values will influence the error probability of the respective system. Among them, the normalized threshold parameter of NT-GSC is generally the most robust to distinct channel conditions. The TR system has close performance to the dual pulse system with either GSC, AT-GSC or NT-GSC in CM2 to CM4. In the CM1 channel, the transmitted reference scheme slightly outperforms the dual pulse system at the high signal-to-noise ratio (SNR). This is because the channel model CM1 has a line-of-sight component and the majority of the channel energy is concentrated in the first few closely spaced paths, which may result in strong self interference for the dual pulse system and the interference effect becomes more dominant at high SNR's. For CM2 to CM4 channels, the multipaths are more sparsely spread into longer time durations, resulting in less inter-path interference. Moreover, the system performances (both DP and TR) in different channel models degrade from CM1 to CM4, as expected. The degradations from CM1 to CM4, however, are generally not very significant for either the DP or TR system studied, which demonstrates the robustness of the autocorrelation receivers in different channel environments.

The foregoing is a description of one possible embodiment. As would be known to one skilled in the art, variations are contemplated that do not alter the scope of the invention. For example, both binary and non-binary systems can be used.

The described embodiments may be implemented in a variety of hardware and software devices known in the art, or in a combination thereof, including but not limited to: personal computers, workstations, cellular telephones, handheld devices, digital radios, radar devices, VLSI devices, and digital signal processors. Instructions for software implementations of the described embodiments may be stored on any type of computer-readable medium.

### CONCLUSION

A novel dual pulse transmission and auto-correlation detection scheme for UWB communications has been presented. It has several advantages over the conventional transmitted reference scheme, such as higher data rate and implementation edge, while retaining the many benefits a TR system possesses. Theoretical analysis on the performance of several different detection and combining schemes has been carried out and verified by simulations. The proposed dual pulse scheme permits a simple, low cost, and robust UWB transceiver.

I claim:

1. A method of transmitting information on an ultra-wideband system, said method comprising:
repeatedly sending, during a frame interval of time T_{f}, an ultra-wideband pulse of time T_{w}, said ultra-wideband pulse comprising at least two sub-pulses, sub-pulse one, and sub-pulse two, wherein T_{f} is larger than T_{w}; and
repeatedly receiving said ultra-wideband pulse.

2. The method of claim 1 wherein sub-pulse two is identical to sub-pulse one.

3. The method of claim 2 wherein said sub-pulses are contiguous.

4. The method of claim 3 further comprising modulating at least one of the sub-pulses according to a modulation scheme.

5. The method of claim 4 wherein said modulation scheme is on-off keying.

6. The method of claim 4 wherein said modulation scheme is pulse position modulation.

7. The method of claim 1 wherein sub-pulse two is inverse to sub-pulse one.

8. The method of claim 7 further comprising modulating at least one of the sub-pulses according to a modulation scheme.

9. The method of claim 8 wherein said modulation scheme is binary pulse amplitude modulation.

10. The method of claim 8 wherein said modulation scheme is pulse amplitude modulation.

11. The method of claim 5 wherein sending the ultra-wideband pulse comprises using multiple access techniques.

12. The method of claim 11 wherein said multiple access technique comprises time-hopping.

13. The method of claim 11 wherein said multiple access technique comprises spreading sequence.

14. The method of claim 6 wherein sending the ultra-wideband pulse comprises using multiple access techniques.

15. The method of claim 14 wherein said multiple access technique comprises time-hopping.

16. The method of claim 14 wherein said multiple access technique comprises spreading sequence.

17. The method of claim 8 wherein sending the ultra-wideband pulse comprises using multiple access techniques.

18. The method of claim 17 wherein said multiple access technique comprises time-hopping.

19. The method of claim 17 wherein said multiple access technique comprises spreading sequence.

20. The method of claim 9 wherein sending the ultra-wideband pulse comprises using multiple access techniques.

21. The method of claim 20 wherein said multiple access technique comprises time-hopping.

22. The method of claim 21 wherein said multiple access technique comprises spreading sequence.

23. The method of claim 1 further comprising receiving said ultra-wideband pulse using an auto-correlation receiver.

24. A transmission system for transmitting an ultra-wideband pulse, said system operative to repeatedly send at least one ultra-wideband pulse during a frame interval of time T_{f}, comprising:
a transmitter operative to send an ultra-wideband pulse of time T_{w}, said ultra-wideband pulse comprising at least two sub-pulses, sub-pulse one and sub-pulse two, wherein T_{f} is larger than T_{w}; and
a receiver operative to repeatedly receive said ultra-wideband pulse.

25. The system of claim 24 wherein said transmitter is operative to send identical sub-pulse two and sub-pulse one.

26. The system of claim 25, wherein at least part of the ultra-wideband pulse is modulated according to the on-off keying modulation scheme.

27. The system of claim 26, wherein said sub-pulses are contiguous.

28. The system of claim 27, wherein at least part of the ultra-wideband pulse is modulated according to the pulse position modulation scheme.

29. The system of claim 24 wherein said transmitter is operative to send sub-pulse two inverse to sub-pulse one.

30. The system of claim 29, wherein at least one of the sub-pulses is modulated according to the binary pulse amplitude modulation scheme.

31. The system of claim 29, wherein at least one of the sub-pulses is modulated according to the pulse amplitude modulation scheme.

32. A computer-readable medium containing instructions that when executed cause a computer to carry out a method of transmitting information on an ultra-wideband system, said method comprising:
sending repeatedly, during a frame interval of time T_{f}, an ultra-wideband pulse of time T_{w}, said ultra-wideband pulse comprising at least two sub-pulses, sub-pulse one and sub-pulse two, wherein, T_{f} is larger than T_{w}; and
receiving said ultra-wideband pulse repeatedly.

33. The computer-readable medium of claim 32, said method further comprising repeatedly sending and receiving said ultra-wideband pulse contiguously within a frame.

34. The computer-readable medium of claim 33 wherein sub-pulse two is identical to sub-pulse one.

35. The computer-readable medium of claim 34, said method further comprising modulating at least one of the sub-pulses according to a modulation scheme.

36. The computer-readable medium of claim 33 wherein sub-pulse two is inverse to sub-pulse one.

37. The computer-readable medium of claim 36, said method further comprising modulating at least one of the sub-pulses according to a modulation scheme.
